(19) United States
(12) Patent Application Publication
(10) Pub. No.: US 2013/0247951 A1
(43) Pub. Date: Sep. 26, 2013

(54) THERMOELECTRIC MATERIAL WITH HIGH CROSS-PLANE ELECTRICAL CONDUCTIVITY IN THE PRESENCE OF A POTENTIAL BARRIER

(71) Applicant: THE BOARD OF REGENTS OF THE UNIVERSITY OF OKLAHOMA, (US)

(72) Inventor: Patrick John McCann, Norman, OK (US)

(73) Assignee: THE BOARD OF REGENTS OF THE UNIVERSITY OF OKLAHOMA, Norman, OK (US)

(21) Appl. No.: 13/834,244

(22) Filed: Mar. 15, 2013

Related U.S. Application Data
(60) Provisional application No. 61/613,015, filed on Mar. 20, 2012.

(51) Int. Cl. H01L 35/16; H01L 35/34

(52) U.S. Cl. CPC H01L 35/16; H01L 35/34
USPC 136/238; 438/54

(57) ABSTRACT

Embodiments of a thermoelectric material having high cross-plane electrical conductivity in the presence of one or more Seebeck coefficient enhancing potential barriers and methods of fabrication thereof are disclosed. In one embodiment, a thermoelectric material includes a first matrix material layer, a barrier layer, and a second matrix material layer. The barrier layer is a short-period superlattice structure that includes multiple superlattice layers. Each superlattice layer has a high energy sub-band and a low energy sub-band. For each superlattice layer, the energy level of the high energy sub-band of the superlattice layer is resonant with the energy level of the low energy level sub-band of an adjacent superlattice layer and/or the energy level of the low energy sub-band of the superlattice layer is resonant with the energy level of the high energy sub-band of an adjacent superlattice layer. As a result, cross-plane electrical conductivity of the thermoelectric material is improved.

### RELATED APPLICATIONS

This application claims the benefit of provisional patent application Ser. No. 61/613,015, filed Mar. 20, 2012, the disclosure of which is hereby incorporated herein by reference in its entirety.

### FIELD OF THE DISCLOSURE

The present disclosure relates to a thermoelectric material and more specifically relates to a thermoelectric material having high cross-plane electrical conductivity.

### BACKGROUND

The figure-of-merit (ZT) of a thermoelectric material is a dimensionless unit that is used to compare the efficiencies of various thermoelectric materials. The figure-of-merit (ZT) is determined by three physical parameters: thermopower α (also known as a Seebeck coefficient); electrical conductivity a; and thermal conductivity k=kₑ+kₚₕ, where kₑ and kₚₕ are thermal conductivities due to transport of electrons and phonons, respectively; and absolute temperature T:

$$ZT = \frac{{α}^{2} σ}{( {k}_{e} + {k}_{ph} )} T .$$

Significant research has been conducted to develop thermoelectric materials having a high figure-of-merit (ZT) value. Increasing this value to 2.0 or higher will disrupt existing technologies and will ultimately enable more widespread use of thermoelectric systems.

U.S. Patent Application Publication No. 2012/0055528, entitled THERMOELECTRIC MATERIALS, which was filed on Mar. 29, 2010 and is hereby incorporated herein by reference in its entirety, discloses a thermoelectric material that utilizes one or more potential barriers to provide an enhanced, or improved, Seebeck coefficient. From the equation above, it can be seen that enhancing the Seebeck coefficient provides an improved figure-of-merit (ZT) value for the thermoelectric material. More specifically, the Seebeck coefficient is defined as an electrical potential of a charge carrier over a temperature differential across which the charge carrier travels. As disclosed in U.S. Patent Application Publication No. 2012/0055528, a potential barrier provides a hot carrier skimming effect by which hot carriers (i.e., hot electrons or hot holes depending on the conductivity type of the thermoelectric material) are skimmed from one side of the potential barrier to the other side of the potential barrier. Thus, the hot carriers that pass across the potential barrier are at a high energy level and thus have a high electrical potential. Because these hot carriers have high electrical potential, the Seebeck coefficient of the thermoelectric material is enhanced. More specifically, by letting a thickness of a barrier material layer be approximately equal to a mean free path distance for charge carriers between scattering events at a desired temperature of the barrier material layer during operation of a corresponding thermoelectric device, ballistic transport of charge carriers through the barrier material layer is enabled, thereby increasing the Seebeck coefficient of the thermoelectric material and thus the figure-of-merit (ZT) value of the thermoelectric material.

What is desired is a thermoelectric material that has enhanced cross-plane electrical conductivity in the presence of one or more Seebeck coefficient enhancing potential barriers and a method of fabrication thereof. The enhanced cross-plane electrical conductivity would further improve the figure-of-merit (ZT) value of the thermoelectric material.

### SUMMARY

Embodiments of a thermoelectric material having high cross-plane electrical conductivity in the presence of one or more Seebeck coefficient enhancing potential barriers and methods of fabrication thereof are disclosed. In one embodiment, a thermoelectric material includes a first matrix material layer, a barrier layer, and a second matrix material layer. The barrier layer is a short-period superlattice structure that includes multiple superlattice layers. Each superlattice layer has two different sub-bands, namely, a high energy sub-band and a low energy sub-band. In one preferred embodiment, the thermoelectric material is a Group IV-VI thermoelectric material grown in the [111] direction, and the high energy sub-band and the low energy sub-band are an oblique valley sub-band and a normal valley sub-band, respectively. For each superlattice layer, the energy level of the high energy sub-band of the superlattice layer is resonant with the energy level of the low energy sub-band of an adjacent superlattice layer and/or the energy level of the low energy sub-band of the superlattice layer is resonant with the energy level of the high energy sub-band of an adjacent superlattice layer. As a result, a resonant path, or resonant tunnel, for hot carriers is created through the barrier layer. The resonant path for hot carriers increases an electrical conductivity of the thermoelectric material and, as a result, improves a figure-of-merit (ZT) of the thermoelectric material.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a thermoelectric material including barrier material layers each having a short-period superlattice structure that provides high cross-plane electrical conductivity in the presence of a potential barrier according to one embodiment of the present disclosure;

FIG. 2 is a more detailed illustration of one of the barrier material layers of FIG. 1 according to one embodiment of the present disclosure;

FIG. 3 graphically illustrates high energy level sub-bands and low energy level sub-bands of each superlattice layer in the short-period superlattice structure of the barrier material layer of FIG. 2 where, for each superlattice layer, the high energy level sub-band is resonant with the low energy level sub-band of an adjacent superlattice layer such that cross-plane electrical conductivity through the barrier material layer is substantially improved according to one embodiment of the present disclosure;

FIG. 4 graphically illustrates the operation of the barrier material layer of FIG. 2 according to one embodiment of the present disclosure;

FIG. 5 illustrates experimental data and theoretical fits to the data for the energy levels of a normal valley sub-band and an oblique valley sub-band of a Lead Strontium Selenide (PbSrSe)/Lead Selenide (PbSe)/PbSrSe superlattice versus quantum well width;

FIG. 6 graphically illustrates quantum well widths that can be utilized to create adjacent superlattice layers having resonant normal and oblique valley sub-bands according to one embodiment of the present disclosure;

FIG. 7 illustrates one embodiment of the barrier material layer of FIG. 2 in which the superlattice layers are PbSrSe/PbSe/PbSrSe superlattice layers having quantum well widths selected such that, for each superlattice layer, the oblique valley sub-band is resonant with the normal valley sub-band of an adjacent superlattice layer according to one embodiment of the present disclosure;

FIG. 8 illustrates another embodiment of the barrier material layer of FIG. 2 in which the superlattice layers are PbSrSe/PbSe/PbSrSe superlattice layers having quantum well widths selected such that, for each superlattice layer, the oblique valley sub-band is resonant with the normal valley sub-band of an adjacent superlattice layer according to one embodiment of the present disclosure;

FIG. 9 illustrates the thermoelectric material of FIG. 1 in which one of the barrier layers of the thermoelectric material is the barrier layer of FIG. 7 and the other barrier layer of the thermoelectric material is the barrier layer of FIG. 8 according to one embodiment of the present disclosure;

FIG. 10 illustrates theoretical curves for the energy levels of a normal valley sub-band and an oblique valley sub-band of a PbSe/Lead Tin Selenide (PbSnSe)/PbSe superlattice versus quantum well width along with quantum well widths that can be utilized to create adjacent superlattice layers having resonant normal and oblique valley sub-bands according to one embodiment of the present disclosure;

FIG. 11 illustrates one embodiment of the barrier material layer of FIG. 2 in which the superlattice layers are PbSe/PbSnSe/PbSe superlattice layers having quantum well widths selected such that, for each superlattice layer, the oblique valley sub-band is resonant with the normal valley sub-band of an adjacent superlattice layer according to one embodiment of the present disclosure;

FIG. 12 illustrates another embodiment of the barrier material layer of FIG. 2 in which the superlattice layers are PbSe/PbSnSe/PbSe superlattice layers having quantum well widths selected such that, for each superlattice layer, the oblique valley sub-band is resonant with the normal valley sub-band of an adjacent superlattice layer according to one embodiment of the present disclosure;

FIG. 13 illustrates the thermoelectric material of FIG. 1 in which one of the barrier layers of the thermoelectric material is the barrier layer of FIG. 11 and the other barrier layer of the thermoelectric material is the barrier layer of FIG. 12 according to one embodiment of the present disclosure; and

FIG. 14 is a flow chart that illustrates a process for designing and fabricating the thermoelectric material of FIG. 1 according to one embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

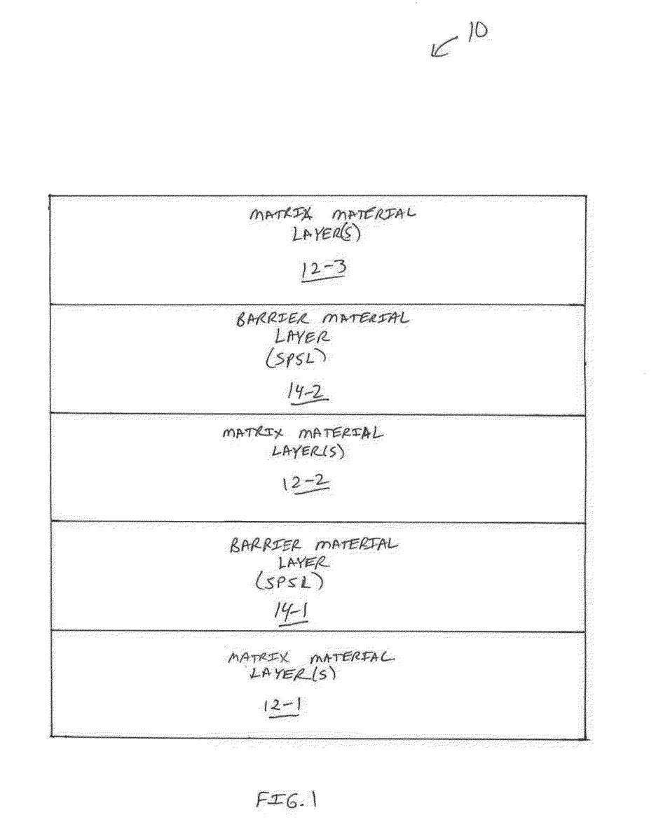

Embodiments of a thermoelectric material having high cross-plane electrical conductivity in the presence of one or more Seebeck coefficient enhancing potential barriers and methods of fabrication thereof are disclosed. In this regard, FIG. 1 illustrates a thermoelectric material 10 having high cross-plane electrical conductivity in the presence of Seebeck coefficient enhancing potential barriers according to one embodiment of the present disclosure. In this embodiment, the thermoelectric material 10 includes matrix material layers 12-1 through 12-3 (generally referred to herein collectively as matrix material layers 12 and individually as matrix material layer 12) and barrier material layers 14-1 and 14-2 (generally referred to herein collectively as barrier material layers 14 and individually as barrier material layer 14) arranged as shown. In general, a bandgap of each of the barrier material layers 14 is greater than a bandgap of the adjacent matrix material layers 12 such that the barrier material layers 14 provide potential barriers. Notably, a height of the potential barrier (i.e., the barrier height) created by the barrier material layer 14-1 and the adjacent matrix material layers 12-1 and 12-2 may be the same as or different than a height of the potential barrier created by the barrier material layer 14-2 and the adjacent matrix material layers 12-2 and 12-3. While two barrier material layers 14-1 and 14-2 are illustrated in the embodiment of FIG. 1, the thermoelectric material 10 may include any number of one or more barrier material layers 14.

As taught in U.S. Patent Application Publication No. 2012/0055528, which has been incorporated herein by reference in its entirety, the potential barriers created by the barrier material layers 14 enhance a Seebeck coefficient of the thermoelectric material 10. More specifically, the Seebeck coefficient is defined as an electrical potential of a charge carrier over a temperature differential across which the charge carrier travels. Each of the potential barriers created by the barrier material layers 14 provides a hot carrier skimming effect by which hot carriers (i.e., hot electrons or hot holes depending on the conductivity type of the thermoelectric material 10) are skimmed from one side of the potential barrier to the other side of the potential barrier. Thus, the hot carriers that pass across the potential barrier are at a high energy level and, as such, have a high electrical potential. Because these hot carriers have high electrical potential, the Seebeck coefficient of the thermoelectric material 10 is enhanced.

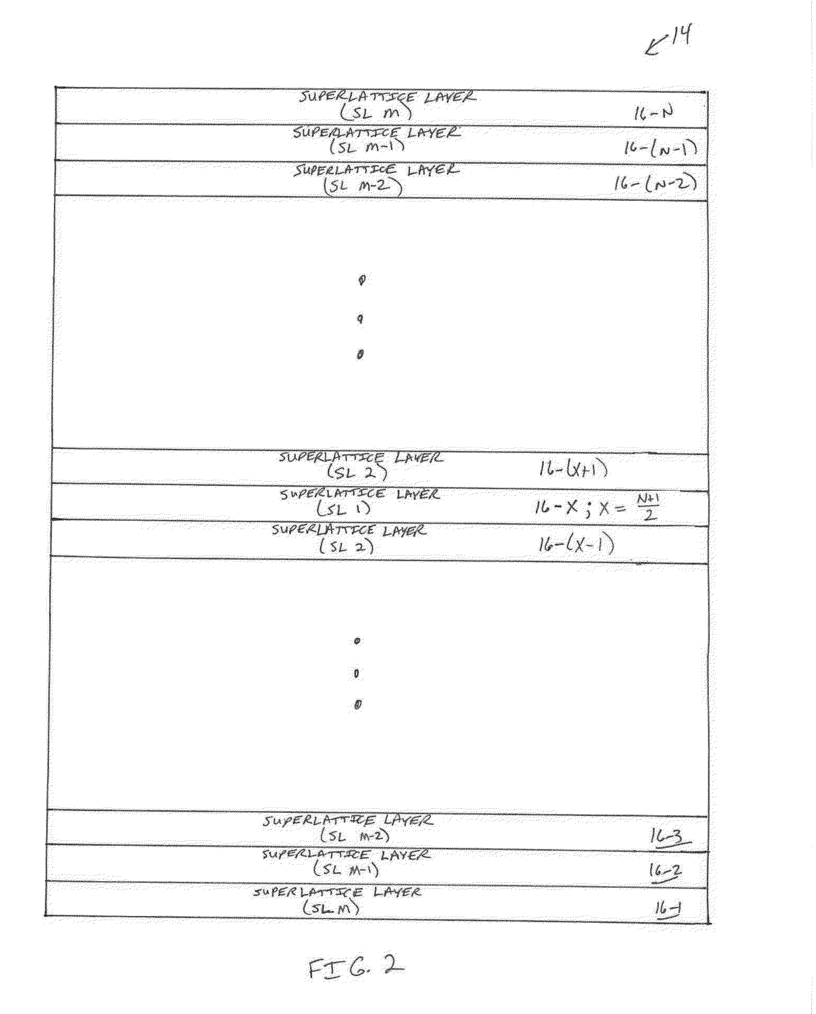

Each of the barrier material layers 14 has a short-period superlattice (SPSL) structure (i.e., is a short-period superlattice) that enhances a cross-plane electrical conductivity of the barrier material layer 14 in the presence of the potential barrier created by the barrier material layer 14. A superlattice is a periodic structure of alternating layers of two (or more) different materials. As used herein, a short-period superlattice is a superlattice in which a thickness of each individual layer of the superlattice is less than or equal to about 20 nanometers (nm). As illustrated in FIG. 2, each of the barrier material layers 14 has a short-period superlattice structure that includes multiple superlattice layers 16-1 through 16-N, where N is greater than 1 and is more preferably greater than or equal to 3. Note that the number of superlattice layers 16-1 through 16-N may be the same or different for different barrier material layers 14. The superlattice layers 16-1 through 16-N are more generally referred to herein collectively as superlattice layers 16 and individually as superlattice layer 16.

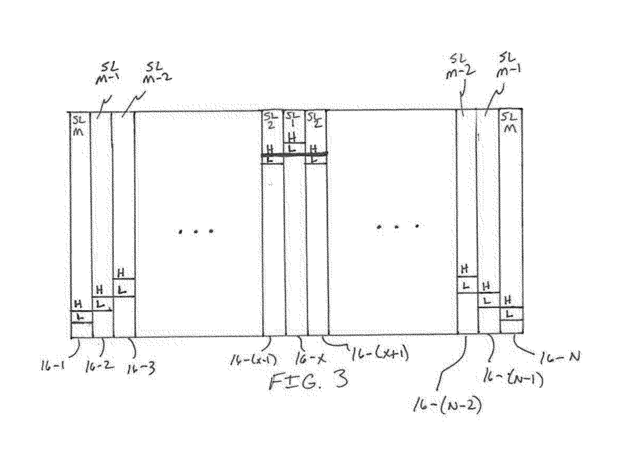

As discussed below in detail, rather than having a continuum of allowable states for charge carriers, each of the superlattice layers 16 of the barrier material layer 14 includes two sub-bands at different energy levels, namely, a high energy sub-band and a low energy sub-band. As illustrated in FIG. 3, the energy levels of the high energy sub-bands (H) and the low energy sub-bands (L) of the superlattice layers 16 are selected such that the barrier material layer 14 provides a desired potential barrier to enhance the Seebeck coefficient of the thermoelectric material 10 while at the same time the barrier material layer 14 enhances, or improves, transport of charge carriers through the potential barrier. Enhanced transport of charge carriers, which in FIG. 3 are electrons, through the barrier material layer 14 is achieved by configuring the superlattice layers 16 such that, for each superlattice layer 16, the high energy sub-band of the superlattice layer 16 is resonant with the low energy sub-band of an adjacent superlattice layer 16 and/or the low energy sub-band of the superlattice layer 16 is resonant with the high energy sub-band of an adjacent superlattice layer 16.

More specifically, as illustrated in FIG. 3, the superlattice layer 16-X (X=(N+1)/2) has a maximum bandgap of the barrier material layer 14. In other words, the energy level of the high energy sub-band of the superlattice layer 16-X is the highest energy level among the high energy sub-bands of the superlattice layers 16. The energy levels of the sub-bands of the superlattice layers 16-1 through 16-(X−1) provide a stair-step increase from the bandgap of the adjacent matrix material layer 12 to the maximum bandgap of the barrier material layer 14 provided by the superlattice layer 16-X. The high energy sub-band (H) of each of the superlattice layers 16-1 through 16-(X−1) is resonant with the low energy sub-band (L) of an immediately succeeding superlattice layer 16 in the short-period superlattice structure. Specifically, the high energy sub-band (H) of the superlattice layer 16-1 is resonant with the low energy sub-band (L) of the superlattice layer 16-2, the high energy sub-band (H) of the superlattice layer 16-2 is resonant with the low energy sub-band (L) of the superlattice layer 16-3, and so on. Likewise, the energy levels of the sub-bands of the superlattice layers 16-(X+1) to 16-N provide a stair-step decrease from the maximum bandgap provided by the superlattice layer 16-X to the bandgap of the adjacent matrix material layer 12. The high energy sub-band (H) of each of the superlattice layers 16-(X+1) through 16-N is resonant with the low energy sub-band (L) of an immediately preceding superlattice layer 16 in the short-period superlattice structure. Specifically, the high energy sub-band (H) of the superlattice layer 16-(X+1) is resonant with the low energy sub-band (L) of the superlattice layer 16-X, the high energy sub-band (H) of the superlattice layer 16-(X+2) is resonant with the low energy sub-band (L) of the superlattice layer 16-(X+1), and so on. As used herein, two sub-bands are resonant when the bottom energy levels of the two sub-bands are equal.

The resonant sub-bands in the superlattice layers 16-(X−1), 16-X, and 16-(X+1) provide a resonant path, or resonant tunnel, through the potential barrier created by the barrier material layer 14. In addition, assuming that electron flow is from left to right in FIG. 3, the resonant sub-bands between the superlattice layers 16-1 through 16-(X−1) enable more efficient transport of electrons through the potential barrier created by the barrier material layer 14. Specifically, the resonant sub-bands of the superlattice layers 16-1 and 16-2 enable electrons to move from the high energy sub-band (H) of the superlattice layer 16-1 to the low energy sub-band (L) of the superlattice layer 16-2 without any loss of energy. In this manner, the electrons are efficiently moved from the superlattice layer 16-1 to the superlattice layer 16-2 and, therefore, are closer to moving through the potential barrier. As a result of the resonant path and the more efficient transport of electrons through the potential barrier, the cross-plane electrical conductivity of the thermoelectric material 10 is enhanced, or increased, which in turn improves the figure-of-merit (ZT) of the thermoelectric material 10.

Before proceeding, it should be noted that the superlattice structure of the barrier material layer 14 of FIGS. 2 and 3 is symmetrical. More specifically, the superlattice layers 16-1 and 16-N are the same (i.e., have the same superlattice layer structure SL M), the superlattice layers 16-2 and 16-(N−1) are the same (i.e., have the same superlattice layer structure SL M−1), the superlattice layers 16-3 and 16-(N−2) are the same (i.e., have the same superlattice layer structure SL M−2), and so on. However, the barrier material layer 14 is not limited to being symmetrical and may alternatively be asymmetrical.

It should also be noted that the superlattice layers 16 may further be configured to reflect phonons and thereby decrease a thermal conductivity of the thermoelectric material 10 (and therefore increase the figure-of-merit (ZT) of the thermoelectric material 10) as discussed in U.S. Patent Application Publication No. 2013/0009132, entitled LOW THERMAL CONDUCTIVITY MATERIAL, which was filed on Jun. 29, 2012 and is hereby incorporated herein by reference in its entirety. More specifically, the superlattice layers 16 include, for each phonon wavelength to be reflected or blocked, multiple layers of one material composition each having a thickness approximately equal to a quarter of the phonon wavelength and multiple layers of another material composition each having a thickness approximately equal to a quarter of the phonon wavelength. Thus, the sub-layers within the superlattice layers 16 can be optimized to both provide resonant sub-bands as described above and to block multiple phonon wavelengths.

In one preferred embodiment, the thermoelectric material 10 is a Group IV-VI thermoelectric material grown in the [111] direction, and the high energy sub-bands and the low energy sub-bands of the superlattice layers 16 are oblique valley sub-bands and normal valley sub-bands, respectively. More specifically, in this preferred embodiment, each of the superlattice layers 16 is a Group IV-VI quantum well material having one or more quantum wells. Energy levels for electrons and holes in Group IV-VI semiconductor quantum well materials can be calculated using Schrödinger's one-dimensional time-independent equation:

$$\frac{{\partial }^{2} Ψ ( x )}{\partial {x}^{2}} + \frac{2 m}{{ℏ}^{2}} [ E - V ( x ) ] Ψ ( x ) = 0$$

where Ψ(x) is a wavefunction describing the charge carrier, V(x) is a potential function describing the quantum well or superlattice layer, m is a mass of the charge carrier, and ç is Planck's constant. The equation above can be solved, with given boundary conditions and charge carrier masses, to calculate the energy levels, E, of the sub-bands in the Group IV-VI quantum well material (i.e., the Group IV-VI superlattice layer 16). It is known that quantum confinement in the [111] direction removes L-valley band degeneracy in Group IV-VI semiconductor materials resulting in charge carriers (i.e., electrons or holes) with two different effective masses and thus two different allowed energy levels. While not essential, for more information, the interested reader is directed to H. Z. Wu, N. Dai, M. B. Johnson, P. J. McCann, and Z. S. Shi, “Unambiguous Observation of Subband Transitions from Longitudinal Valley and Oblique Valleys in IV-VI Multiple Quantum Wells,” Applied Physics Letters, Vol. 78, No. 15, Apr. 9, 2011, pages 2199-2201. The low energy sub-band is for electrons, or charge carriers, in what is referred to as a normal valley or longitudinal valley, while the high energy sub-band is for electrons, or charge carriers, in what is referred to as a three-fold degenerate oblique valley. As such, for Group IV-VI, the low energy sub-band is more specifically referred to as a normal valley sub-band, and the high energy sub-band is more specifically referred to as an oblique valley sub-band.

As discussed below in detail, each of the superlattice layers 16 in the barrier material layer 14 includes one or more quantum wells. The energy levels of the normal and oblique valley sub-bands for each of the superlattice layers 16 are a function of a quantum well width of the individual quantum wells in that superlattice layer 16. The quantum well thicknesses for the superlattice layers 16 are selected such that the barrier material layer 14 provides the desired potential barrier to enhance the Seebeck coefficient of the thermoelectric material 10 while at the same time enhancing, or increasing, transport of charge carriers through the potential barrier. More specifically, in a manner similar to that discussed above with respect to FIG. 3, the quantum well widths for the superlattice layers 16 are selected such that, for each of the superlattice layers 16-1 through 16-(X−1), the oblique valley sub-band of the superlattice layer 16 is resonant with the normal valley sub-band of the immediately succeeding superlattice layer 16 in the short period superlattice structure of the barrier material layer 14 and, for each of the superlattice layers 16-(X+1) through 16-N, the oblique valley sub-band of the superlattice layer 16 is resonant with the normal valley sub-band of the immediately preceding superlattice layer 16 in the short period superlattice structure of the barrier material layer 14.

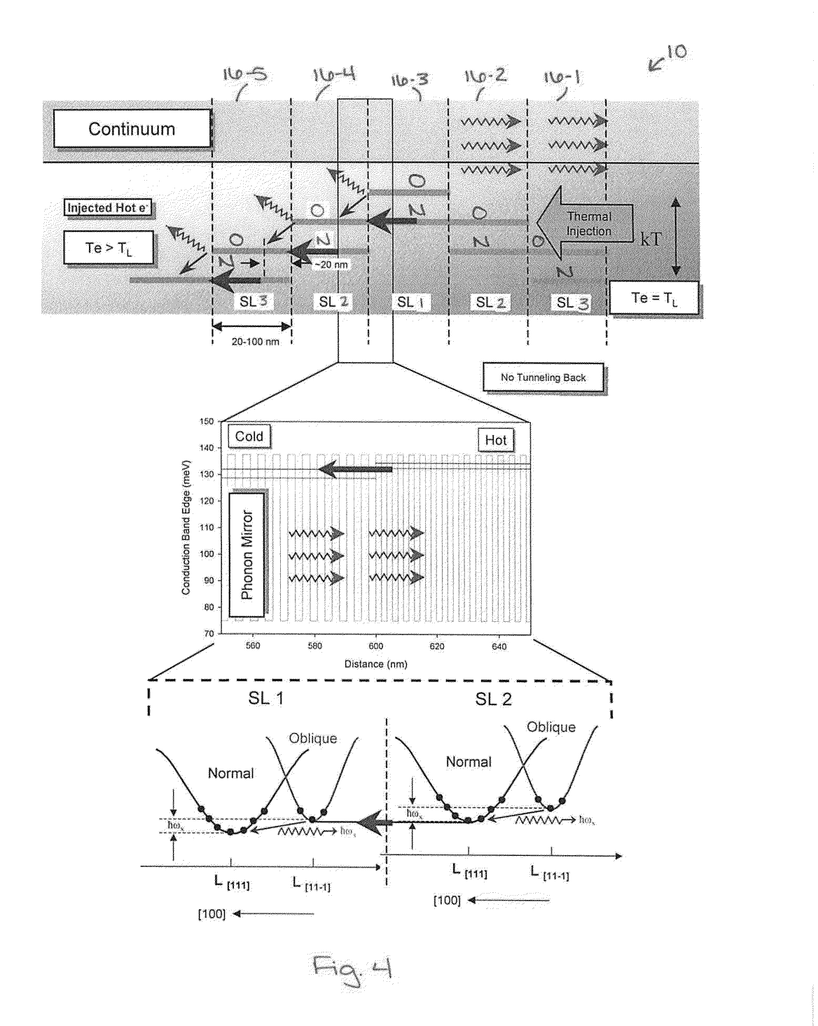

FIG. 4 illustrates the operation of the superlattice structure of the barrier material layer 14 in more detail for one example of the barrier material layer 14. In this example, the superlattice layers 16 are Group IV-VI superlattice lattice layers. Further, in this example, the thermoelectric material 10 is utilized in a waste heat harvesting or power generation application where electrons are thermally injected into the barrier material layer 14 from right to left. Note, however, that this discussion is equally applicable to cooling applications (Peltier effect applications). As illustrated, the quantum well widths of the superlattice layers 16 are selected such that the normal valley sub-bands (N) and the oblique valley sub-bands (O) are arranged as illustrated to thereby create a desired potential barrier while also improving cross-plane electrical conductivity. Due to thermal excitation, a large number of electrons occupy high energy levels in the right-most superlattice layers 16 (i.e., the superlattice layers 16-1 and 16-2). These high energy electrons pass over or through the potential barrier. Notably, a resonant path created from the oblique valley sub-band (O) of the superlattice layer 16-2 to the normal valley sub-band (N) of the superlattice layer 16-3 to the oblique valley sub-band (O) of the superlattice layer 16-4. Electrons flow through this resonant path without any loss of energy, but do have a change in momentum upon moving from a normal valley sub-band (N) to an oblique valley sub-band (O) or vice versa. The resonant path improves the cross-plane electrical conductivity of the thermoelectric material 10.

Notably, electrons are represented by solid arrows and phonons are represented by jagged or squiggly arrows. As electrons move from the oblique valley sub-band (O) of the superlattice layer 16-3 to the lower energy level oblique valley sub-band (O) of the superlattice layer 16-4, a phonon is released. In a similar manner, a phonon is released when an electron moves from the oblique valley sub-band (O) of the superlattice layer 16-4 to the lower energy level oblique valley sub-band (O) of the superlattice layer 16-5 and again when the electron moves from the oblique valley sub-band (O) of the superlattice layer 16-5 to the lower energy level oblique valley sub-band (O) of the adjacent matrix material layer 12. In this embodiment, the thicknesses of the individual sub-layers of the superlattice layers 16 are selected such that, in addition to providing the desired quantum well thicknesses, the superlattice layers 16 reflect phonons, which in turn decreases the thermal conductivity of the thermoelectric material 10 and, therefore, increases the figure-of-merit (ZT) of the thermoelectric material 10.

In the embodiment of FIG. 4, the thicknesses of the superlattice layers 16 are approximately equal to a mean free path distance of electrons between scattering events. This allows efficient transport of electrons without loss of energy to the lattice. The bottom of FIG. 4 is an energy versus momentum (k) diagram that illustrates the normal valley and oblique valley sub-bands of the superlattice layers 16-3 and 16-4. As illustrated, electrons are transported from the superlattice layer 16-3 to the superlattice layer 16-4 by going from a state in the normal valley sub-band in the superlattice layer 16-3 to a resonant state in the oblique valley sub-band of the superlattice layer 16-4. This transition requires a change in crystal momentum, but a phonon cannot provide this momentum change because there is no accompanying change in energy. Instead, the transition must be assisted by elastic scattering events such as electron-electron interaction. Purely elastic scattering is desirable for thermoelectric materials because it facilitates charge carrier transport from one superlattice layer 16 to the next without dissipating energy to the lattice in the form of phonon generation. The bottom of FIG. 4 also illustrates that, when an electron moves from an oblique valley sub-band to a lower energy level normal valley sub-band (e.g., moves from the oblique valley sub-band of the superlattice layer 16-3 to the normal valley sub-band of the superlattice layer 16-3), a phonon is emitted.

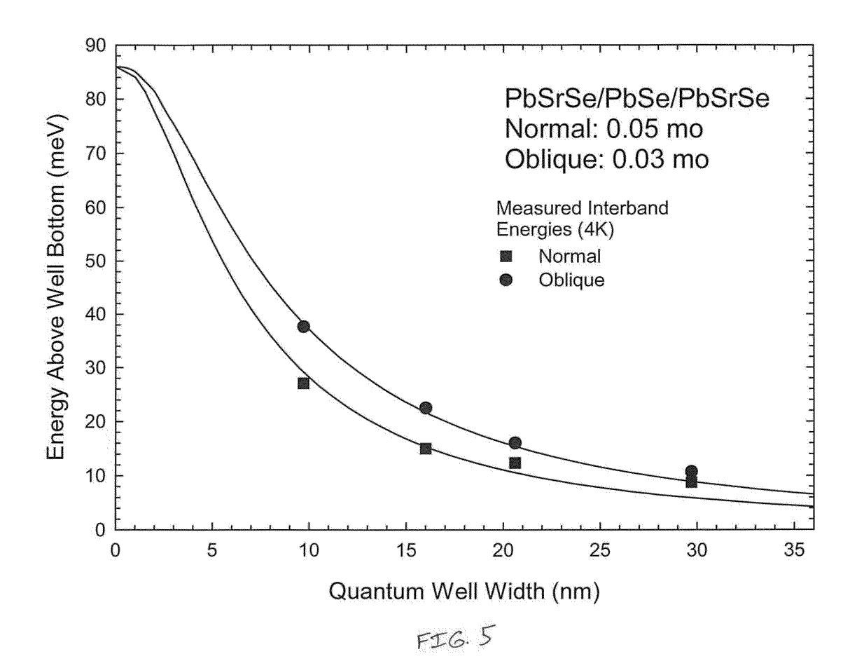

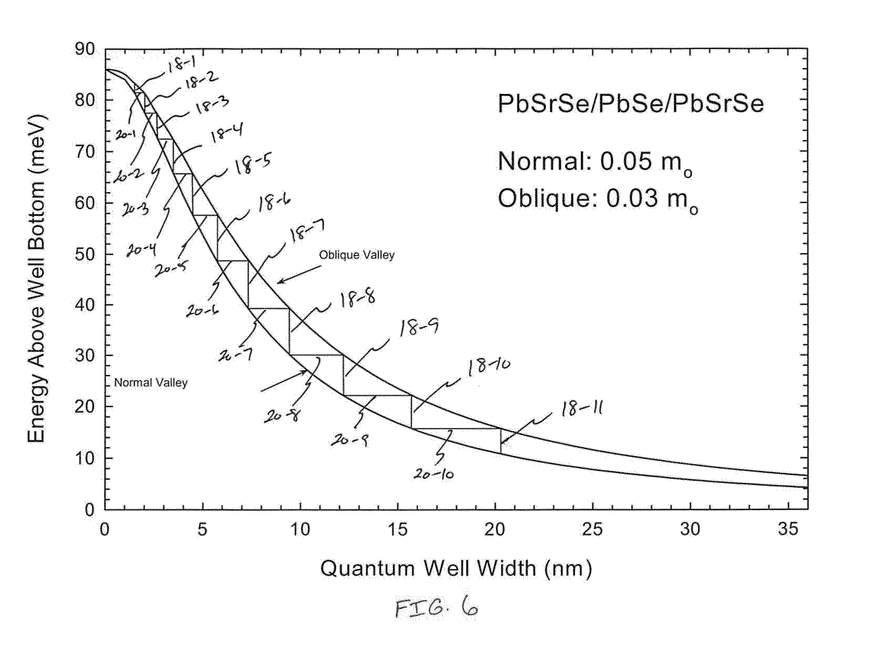

As discussed above, the quantum well widths of the superlattice layers 16 determine the energy levels of the normal valley and oblique valley sub-bands of the superlattice layers 16. As such, only certain combinations of quantum well widths in adjacent superlattice layers will result in the desired potential barrier as well as resonant normal and oblique sub-bands in adjacent superlattice layers 16. FIGS. 5 and 6 graphically illustrate a process by which appropriate combinations of quantum well widths for the superlattice layers 16 can be obtained. In FIGS. 5 and 6, the superlattice layers 16 include alternating layers of Lead Strontium Selenide (PbSrSe) and Lead Selenide (PbSe), where the PbSe layers correspond to quantum wells within the superlattice layers 16. The thickness of the individual PbSe layer(s) (i.e., the quantum well(s)) in a superlattice layer 16 is the quantum well width for the superlattice layer 16.

More specifically, FIG. 5 illustrates experimental sub-band energy data and theoretical fits with effective mass as the only fitting parameter for PbSrSe/PbSe/PbSrSe quantum well materials versus quantum well widths. In this particular example, infrared transmission measurements of the oblique and normal valley sub-bands were obtained for PbSrSe/PbSe/PbSrSe quantum well materials having four different quantum well widths. Theoretical curves, or theoretical plots, for the normal and oblique valley sub-band energies versus quantum well width were then obtained using a theoretical fit of Schrödinger's equation to the measurements using effective mass as the only fitting parameter.

As illustrated in FIG. 6, the theoretical curves of FIG. 5 can be used to determine combinations of quantum well widths that (1) provide the desired potential barrier and (2) give resonant, or the same, normal valley and oblique valley sub-band energy levels in adjacent superlattice layers 16 in the manner described above. As illustrated, a sequence of connected vertical lines 18-1 through 18-11 (more generally referred to herein collectively as vertical lines 18 and individually as vertical line 18) and horizontal lines 20-1 through 20-10 (more generally referred to herein collectively as horizontal lines 20 and individually as horizontal line 20) provides the combinations of quantum well widths that can be used for the superlattice layers 16. The vertical lines 18-1 through 18-11 correspond to different quantum well widths. Each of the horizontal lines 20-1 through 20-10 illustrates the resonant normal and oblique valley sub-bands for quantum well materials that have the quantum well widths corresponding to the two vertical lines 18 connected by the horizontal line 20. In one embodiment, the quantum well width that corresponds to a left-most vertical line 18-1 can be selected as the quantum well width of the superlattice layer 16-X, the quantum well width that corresponds to the next vertical line 18-2 can be selected as the quantum well widths of the superlattice layers 16-(X−1) and 16-(X+1), the quantum well width that corresponds to the next vertical line 18-3 can be selected as the quantum well widths of the superlattice layers 16-(X−2) and 16-(X+2), and so on.

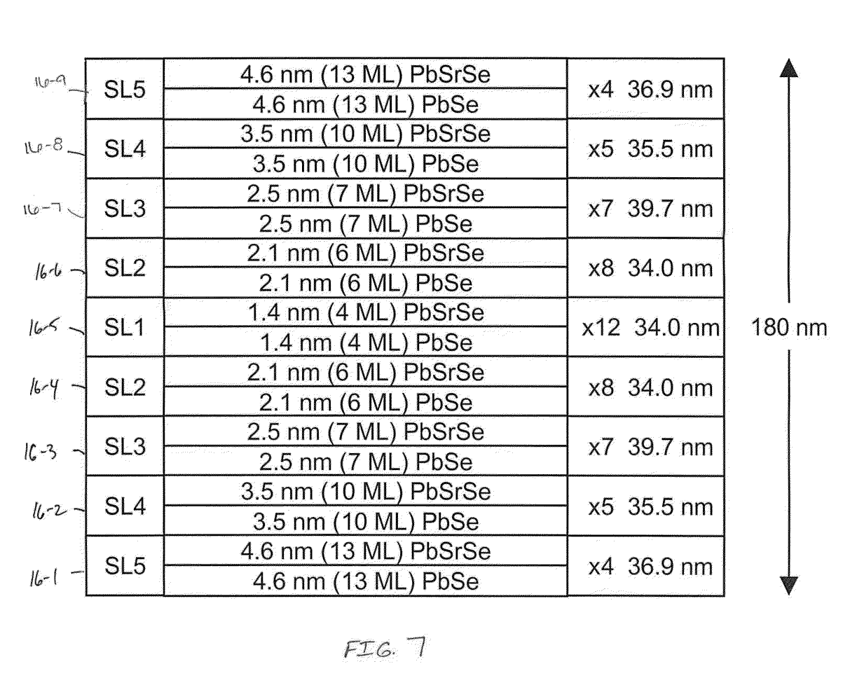

FIG. 7 illustrates one embodiment of the short period superlattice structure of the barrier material layer 14 where the superlattice layers 16 have quantum well widths selected using FIG. 6. In this embodiment, the barrier material layer 14 includes nine superlattice layers 16-1 through 16-9. The quantum well width that corresponds to the vertical line 18-1 of FIG. 6 is selected as the quantum well width for the superlattice layer 16-5, the quantum well width that corresponds to the vertical line 18-2 of FIG. 6 is selected as the quantum well widths for the superlattice layers 16-4 and 16-6, the quantum well width that corresponds to the vertical line 18-3 of FIG. 6 is selected as the quantum well widths for the superlattice layers 16-3 and 16-7, the quantum well width that corresponds to the vertical line 18-4 of FIG. 6 is selected as the quantum well widths for the superlattice layers 16-2 and 16-8, and the quantum well width that corresponds to the vertical line 18-5 of FIG. 6 is selected as the quantum well widths for the superlattice layers 16-1 and 16-9. As a result, the barrier material layer 14 creates a desired potential barrier while at the same time the barrier material layer 14 is such that adjacent superlattice layers 16 have resonant sub-band energies that enhance cross-plane electrical conductivity, as described above.

Each of the superlattice layers 16-1 through 16-9 includes multiple periods of PbSe/PbSrSe. The individual thicknesses of the PbSe layers within the superlattice layers 16-1 through 16-9 are the quantum well widths of the corresponding superlattice layers 16-1 through 16-9. In this embodiment, the number of periods within each superlattice layer 16 is selected such that a total thickness of that superlattice layer 16 is approximately equal to a mean free path distance of electrons between scattering events for a given temperature in a temperature gradient for which the thermoelectric material 10 is designed. Notably, the temperature gradient for which the thermoelectric material 10 is designed is a temperature gradient across the thermoelectric material 10 when incorporated into a thermoelectric device (e.g., a thermoelectric cooler or a thermoelectric power generator) under normal operating conditions. In this example, the thickness of the PbSe and PbSrSe layers within the superlattice layer 16-1 is 4.6 nm or 13 monolayers (ML) (which is the quantum well width that corresponds to the vertical line 18-5 of FIG. 6), and the number of periods in the superlattice layer 16-1 is 4 such that the total thickness of the superlattice layer 16-1 is 36.9 nm; the thickness of the PbSe and PbSrSe layers within the superlattice layer 16-2 is 3.5 nm or 10 ML (which is the quantum well width that corresponds to the vertical line 18-4 of FIG. 6, and the number of periods in the superlattice layer 16-2 is 5 such that the total thickness of the superlattice layer 16-2 is 35.5 nm; and so on. Notably, the superlattice layers 16-1 through 16-9 also operate to reflect phonons with quarter-wavelength values equal to 4.6 nm, 3.5 nm, 2.5 nm, 2.1 nm, and 1.4 nm as taught in U.S. Patent Application Publication No. 2013/0009132.

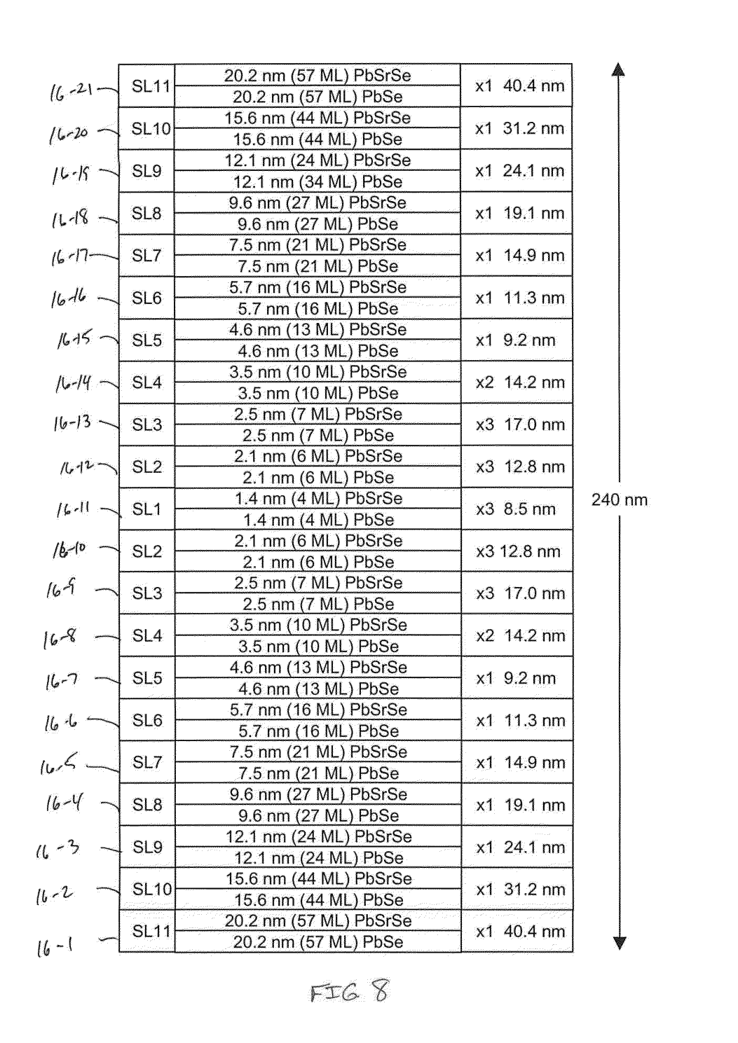

FIG. 8 illustrates another embodiment of the short period superlattice structure of the barrier material layer 14 where the superlattice layers 16 have quantum well widths selected using FIG. 6. In this embodiment, the barrier material layer 14 includes 21 superlattice layers 16-1 through 16-21. The quantum well width that corresponds to the vertical line 18-1 of FIG. 6 is selected as the quantum well width for the superlattice layer 16-11, the quantum well width that corresponds to the vertical line 18-2 of FIG. 6 is selected as the quantum well widths for the superlattice layers 16-10 and 16-12, the quantum well width that corresponds to the vertical line 18-3 of FIG. 6 is selected as the quantum well widths for the superlattice layers 16-9 and 16-13, the quantum well width that corresponds to the vertical line 18-4 of FIG. 6 is selected as the quantum well widths for the superlattice layers 16-8 and 16-14, the quantum well width that corresponds to the vertical line 18-5 of FIG. 6 is selected as the quantum well widths for the superlattice layers 16-7 and 16-15, the quantum well width that corresponds to the vertical line 18-6 of FIG. 6 is selected as the quantum well widths for the superlattice layers 16-6 and 16-16, the quantum well width that corresponds to the vertical line 18-7 of FIG. 6 is selected as the quantum well widths for the superlattice layers 16-5 and 16-17, the quantum well width that corresponds to the vertical line 18-8 of FIG. 6 is selected as the quantum well widths for the superlattice layers 16-4 and 16-18, the quantum well width that corresponds to the vertical line 18-9 of FIG. 6 is selected as the quantum well widths for the superlattice layers 16-3 and 16-19, the quantum well width that corresponds to the vertical line 18-10 of FIG. 6 is selected as the quantum well widths for the superlattice layers 16-2 and 16-20, and the quantum well width that corresponds to the vertical line 18-11 of FIG. 6 is selected as the quantum well widths for the superlattice layers 16-1 and 16-21. As a result, the barrier material layer 14 creates a desired potential barrier while at the same time the barrier material layer 14 is such that adjacent superlattice layers 16 have resonant sub-band energies that enhance cross-plane electrical conductivity, as described above.

Each of the superlattice layers 16-1 through 16-21 includes multiple periods of PbSe/PbSrSe. The individual thicknesses of the PbSe layers within the superlattice layers 16-1 through 16-21 are the quantum well widths of the corresponding superlattice layers 16-1 through 16-21. In this embodiment, the number of periods within each superlattice layer 16 is selected such that a total thickness of the superlattice layer 16 is approximately equal to a mean free path distance of electrons between scattering events for a given temperature in the temperature gradient for which the thermoelectric material 10 is designed. In this example, the thickness of the PbSe and PbSrSe layers within the superlattice layer 16-1 is 20.2 nm or 57 ML (which is the quantum well width that corresponds to the vertical line 18-11 of FIG. 6), and the number of periods in the superlattice layer 16-1 is 1 such that the total thickness of the superlattice layer 16-1 is 40.4 nm; the thickness of the PbSe and PbSrSe layers within the superlattice layer 16-2 is 15.6 nm or 44 ML (which is the quantum well width that corresponds to the vertical line 18-10 of FIG. 6, and the number of periods in the superlattice layer 16-2 is 1 such that the total thickness of that superlattice layer 16-2 is 31.2 nm; and so on. Notably, the superlattice layers 16-1 through 16-21 also operate to reflect phonons with quarter-wavelength values equal to 20.2 nm, 15.6 nm, 12.1 nm, 9.6 nm, 7.5 nm, 5.7 nm, 4.6 nm, 3.5 nm, 2.5 nm, 2.1 nm, and 1.4 nm as taught in U.S. Patent Application Publication No. 2013/0009132.

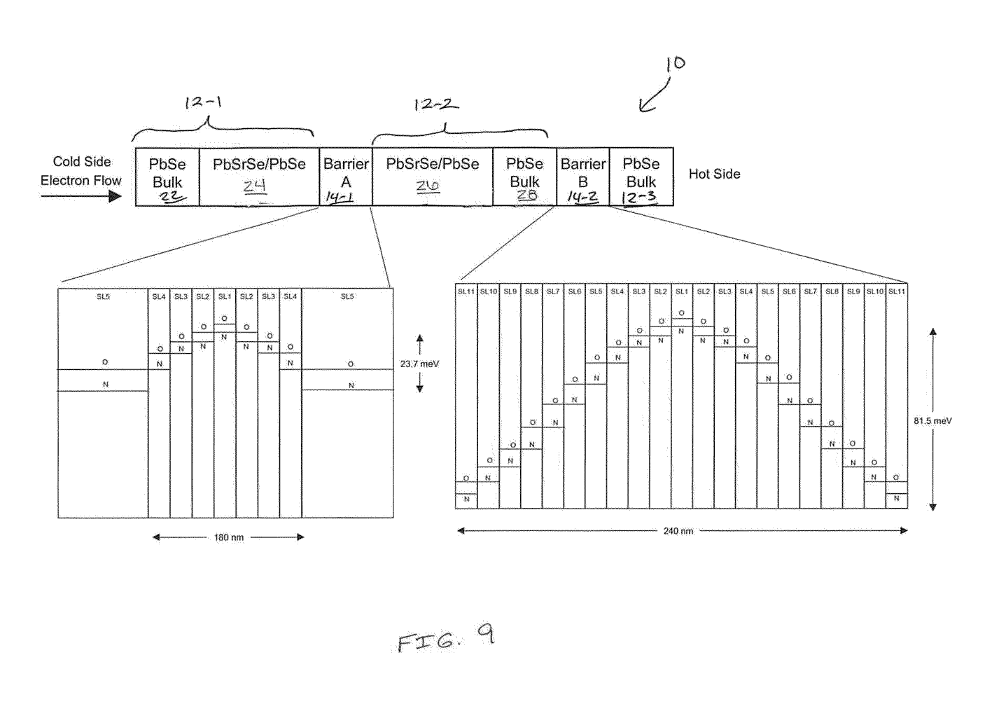

FIG. 9 illustrates one embodiment of the thermoelectric material 10 of FIG. 1 in which the barrier material layer 14-1 is the barrier material layer 14 of FIG. 7 and the barrier material layer 14-2 is the barrier material layer 14 of FIG. 8. In this particular embodiment, the barrier material layer 14-1 is near a cold side of the thermoelectric material 10 during operation whereas the barrier material layer 14-2 is near a hot side of the thermoelectric material 10 during operation. In this embodiment, the matrix material layer 12-1 includes a PbSe bulk layer 22 and a PbSrSe/PbSe superlattice layer 24 having a quantum well width (and thus sub-band energy levels) that is equal to that of the adjacent superlattice layer 16-1 in the barrier material layer 14-1. The superlattice layer 24 effectively lowers a barrier height of the barrier material layer 14-1, which is preferable near the cold side of the thermoelectric material 10. The matrix material layer 12-2 includes a PbSrSe/PbSe superlattice layer 26 having a quantum well width (and thus sub-band energy levels) that is equal to that of the adjacent superlattice layer 16-9 in the barrier material layer 14-1 and a PbSe bulk layer 28. The low band-gap of the PbSe bulk layer 28 increases a barrier height of the barrier material layer 14-2, which is preferable near the hot side of the thermoelectric material 10. In this example, the barrier height of the barrier material layer 14-1 is 23.7 meV, and the barrier height of the barrier material layer 14-2 is 81.5 millielectron volts (meV).

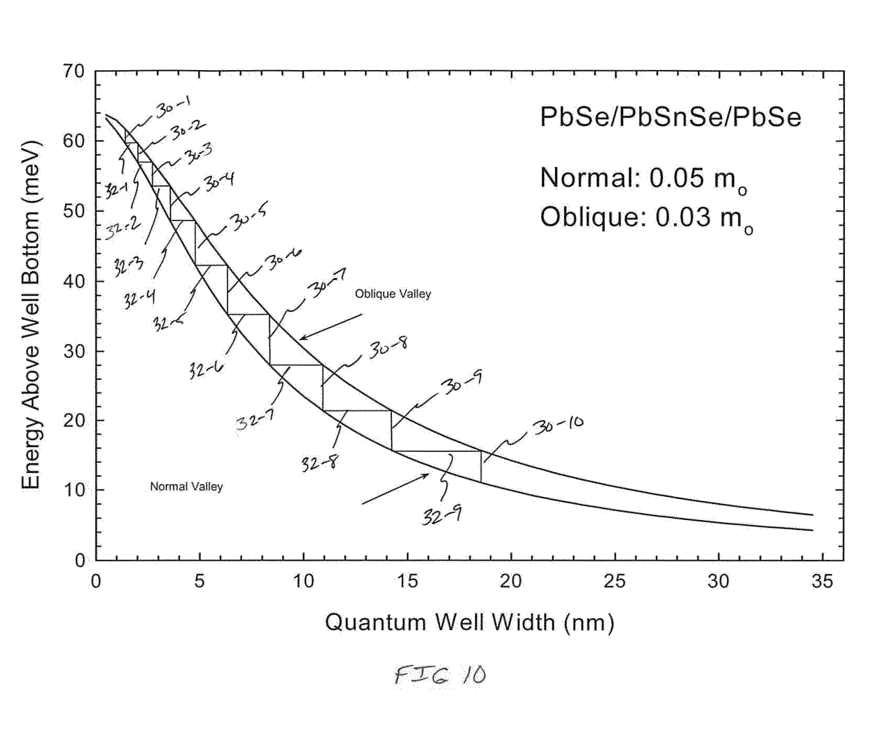

FIGS. 10 through 13 are substantially the same as FIGS. 6 through 9 but for embodiments where PbSe/Lead Tin Selenide (PbSnSe)/PbSe quantum well materials are utilized for the barrier material layers 14 according to another embodiment of the present disclosure. In particular, FIG. 10 graphically illustrates a process by which appropriate combinations of quantum well widths for the superlattice layers 16 can be obtained when using PbSe/PbSnSe/PbSe quantum well materials for the superlattice layers 16. More specifically, FIG. 10 illustrates sub-band energy curves obtained with different effective masses for normal and oblique valleys for PbSe/PbSnSe/PbSe quantum well materials versus quantum well widths. Theoretical curves, or theoretical plots, for the normal and oblique valley sub-band energies versus quantum well width were obtained using Schrödinger's equation with different effective masses for the normal and oblique valley sub-bands.

As illustrated, the theoretical curves of FIG. 10 can be used to determine combinations of quantum well widths that (1) provide the desired potential barrier and (2) give resonant, or the same, normal and oblique valley sub-band energy levels in adjacent superlattice layers 16 in the manner described above. As illustrated, a sequence of connected vertical lines 30-1 through 30-10 (more generally referred to herein collectively as vertical lines 30 and individually as vertical line 30) and horizontal lines 32-1 through 32-9 (more generally referred to herein collectively as horizontal lines 32 and individually as horizontal line 32) provides the combinations of quantum well widths that can be used for the superlattice layers 16. The vertical lines 30-1 through 30-10 correspond to different quantum well widths. Each of the horizontal lines 32-1 through 32-9 illustrates the resonant normal and oblique valley sub-bands for quantum well materials that have the quantum well widths corresponding to the two vertical lines 30 connected by the horizontal line 32. In one embodiment, the quantum well width that corresponds to a left-most vertical line 30-1 can be selected as the quantum well width of the superlattice layer 16-X, the quantum well width that corresponds to the next vertical line 30-2 can be selected as the quantum well widths of the superlattice layers 16-(X−1) and 16-(X+1), the quantum well width that corresponds to the next vertical line 30-3 can be selected as the quantum well widths of the superlattice layers 16-(X−2) and 16-(X+2), and so on.

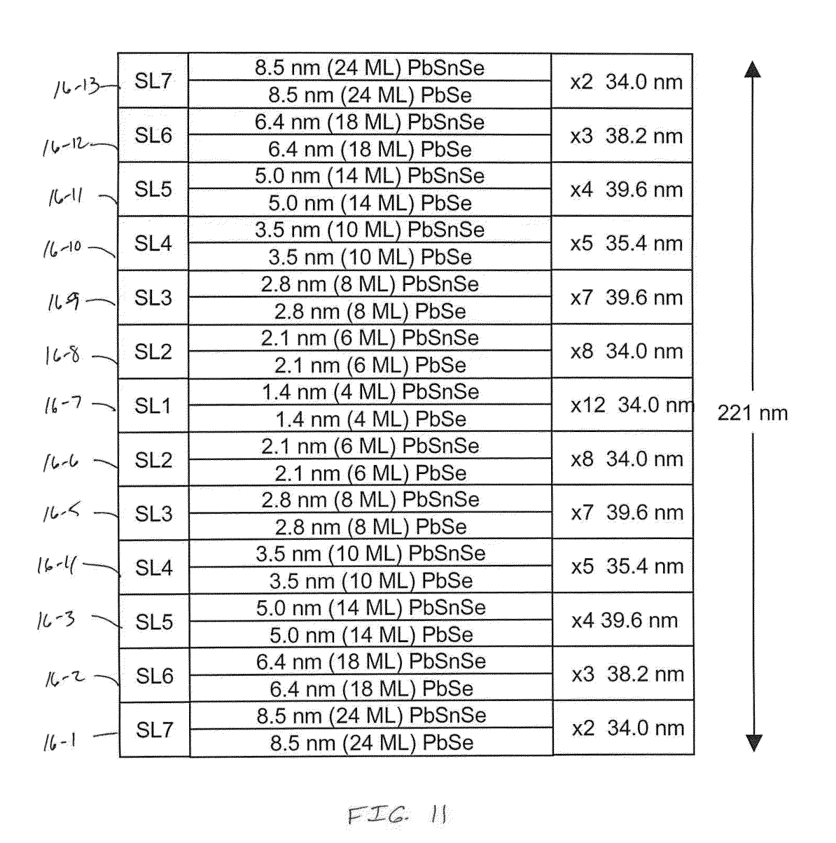

FIG. 11 illustrates one embodiment of the short period superlattice structure of the barrier material layer 14 where the superlattice layers 16 have quantum well widths selected using FIG. 10. In this embodiment, the barrier material layer 14 includes 13 superlattice layers 16-1 through 16-13. The quantum well width that corresponds to the vertical line 30-1 of FIG. 10 is selected as the quantum well width for the superlattice layer 16-7, the quantum well width that corresponds to the vertical line 30-2 of FIG. 10 is selected as the quantum well widths for the superlattice layers 16-6 and 16-8, the quantum well width that corresponds to the vertical line 30-3 of FIG. 10 is selected as the quantum well widths for the superlattice layers 16-5 and 16-9, the quantum well width that corresponds to the vertical line 30-4 of FIG. 10 is selected as the quantum well widths for the superlattice layers 16-4 and 16-10, the quantum well width that corresponds to the vertical line 30-5 of FIG. 10 is selected as the quantum well widths for the superlattice layers 16-3 and 16-11, the quantum well width that corresponds to the vertical line 30-6 of FIG. 10 is selected as the quantum well widths for the superlattice layers 16-2 and 16-12, and the quantum well width that corresponds to the vertical line 30-7 of FIG. 10 is selected as the quantum well widths for the superlattice layers 16-1 and 16-13. As a result, the barrier material layer 14 creates a desired potential barrier while at the same time the barrier material layer 14 is such that adjacent superlattice layers 16 have resonant sub-band energies that enhance cross-plane electrical conductivity, as described above.

Each of the superlattice layers 16-1 through 16-13 includes multiple periods of PbSe/PbSnSe. The individual thicknesses of the PbSnSe layers within the superlattice layers 16-1 through 16-13 are the quantum well widths of the corresponding superlattice layers 16-1 through 16-13. In this embodiment, the number of periods within each superlattice layer 16 is selected such that a total thickness of that superlattice layer 16 is approximately equal to a mean free path distance of electrons between scattering events for a given temperature in the temperature gradient for which the thermoelectric material 10 is designed. In this example, the thickness of the PbSe and PbSnSe layers within the superlattice layer 16-1 is 8.5 nm or 24 MLs (which is the quantum well width that corresponds to the vertical line 30-7 of FIG. 10), and the number of periods in the superlattice layer 16-1 is 2 such that the total thickness of the superlattice layer 16-1 is 34 nm; the thickness of the PbSe and PbSnSe layers within the superlattice layer 16-2 is 6.4 nm or 18 MLs (which is the quantum well width that corresponds to the vertical line 30-6 of FIG. 10), and the number of periods in the superlattice layer 16-2 is 3 such that the total thickness of the superlattice layer 16-2 is 38.2 nm; and so on. Notably, the superlattice layers 16-1 through 16-13 also operate to reflect phonons with quarter-wavelength values equal to 8.5 nm, 6.4 nm, 5.0 nm, 3.5 nm, 2.8 nm, 2.1 nm, and 1.4 nm as taught in U.S. Patent Application Publication No. 2013/0009132.

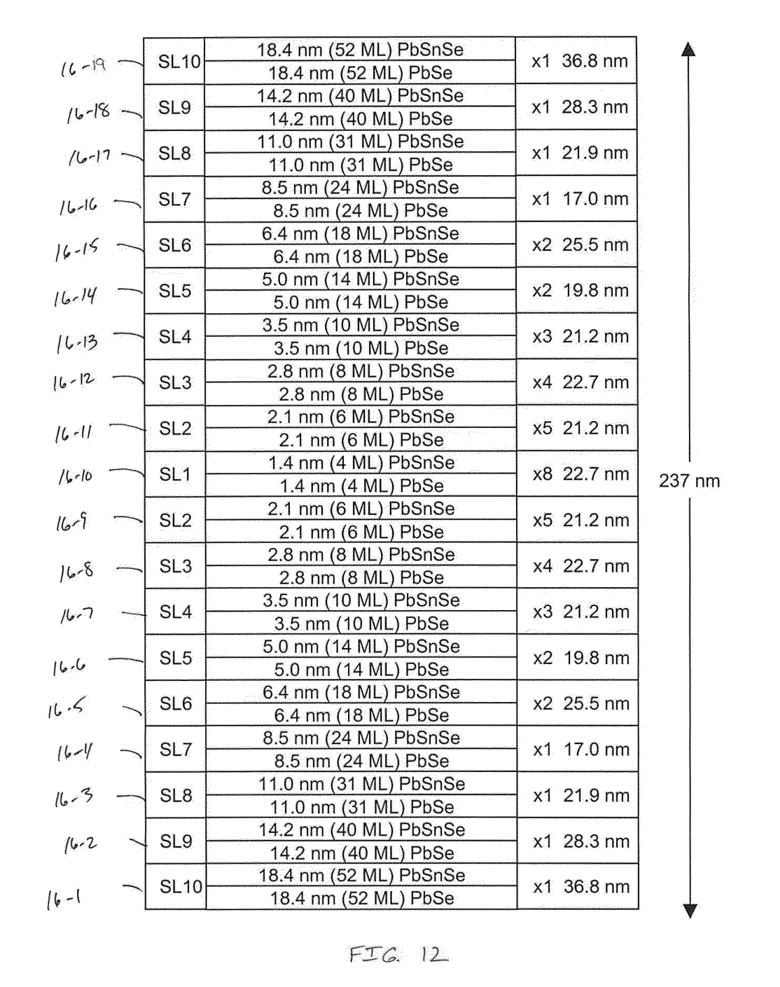

FIG. 12 illustrates another embodiment of the short period superlattice structure of the barrier material layer 14 where the superlattice layers 16 have quantum well widths selected using FIG. 10. In this embodiment, the barrier material layer 14 includes 19 superlattice layers 16-1 through 16-19. The quantum well width that corresponds to the vertical line 30-1 of FIG. 10 is selected as the quantum well width for the superlattice layer 16-10, the quantum well width that corresponds to the vertical line 30-2 of FIG. 10 is selected as the quantum well widths for the superlattice layers 16-9 and 16-11, the quantum well width that corresponds to the vertical line 30-3 of FIG. 10 is selected as the quantum well widths for the superlattice layers 16-8 and 16-12, the quantum well width that corresponds to the vertical line 30-4 of FIG. 10 is selected as the quantum well widths for the superlattice layers 16-7 and 16-13, the quantum well width that corresponds to the vertical line 30-5 of FIG. 10 is selected as the quantum well widths for the superlattice layers 16-6 and 16-14, the quantum well width that corresponds to the vertical line 30-6 of FIG. 10 is selected as the quantum well widths for the superlattice layers 16-5 and 16-15, the quantum well width that corresponds to the vertical line 30-7 of FIG. 10 is selected as the quantum well widths for the superlattice layers 16-4 and 16-16, the quantum well width that corresponds to the vertical line 30-8 of FIG. 10 is selected as the quantum well widths for the superlattice layers 16-3 and 16-17, the quantum well width that corresponds to the vertical line 30-9 of FIG. 10 is selected as the quantum well widths for the superlattice layers 16-2 and 16-18, and the quantum well width that corresponds to the vertical line 30-10 of FIG. 10 is selected as the quantum well widths for the superlattice layers 16-1 and 16-19. As a result, the barrier material layer 14 creates a desired potential barrier while at the same time the barrier material layer 14 is such that adjacent superlattice layers 16 have resonant sub-band energies that enhance cross-plane electrical conductivity, as described above.

Each of the superlattice layers 16-1 through 16-19 includes multiple periods of PbSe/PbSnSe. The individual thicknesses of the PbSnSe layers within the superlattice layers 16-1 through 16-19 are the quantum well widths of the corresponding superlattice layers 16-1 through 16-19. In this embodiment, the number of periods within each superlattice layer 16 is selected such that a total thickness of the superlattice layer 16 is approximately equal to a mean free path distance of electrons between scattering events for a given temperature in the temperature gradient for which the thermoelectric material 10 is designed. In this example, the thickness of the PbSe and PbSnSe layers within the superlattice layer 16-1 is 18.4 nm or 52 ML (which is the quantum well width that corresponds to the vertical line 30-10 of FIG. 10), and the number of periods in the superlattice layer 16-1 is 1 such that the total thickness of the superlattice layer 16-1 is 36.8 nm; the thickness of the PbSe and PbSnSe layers within the superlattice layer 16-2 is 14.2 nm or 40 ML (which is the quantum well width that corresponds to the vertical line 30-9 of FIG. 10), and the number of periods in the superlattice layer 16-2 is 1 such that the total thickness of that superlattice layer 16-2 is 28.3 nm; and so on. Notably, the superlattice layers 16-1 through 16-19 also operate to reflect phonons with quarter-wavelength values equal to 18.4 nm, 14.2 nm, 11.0 nm, 8.5 nm, 6.4 nm, 5.0 nm, 3.5 nm, 2.8 nm, 2.1 nm, and 1.4 nm as taught in U.S. Patent Application Publication No. 2013/0009132.

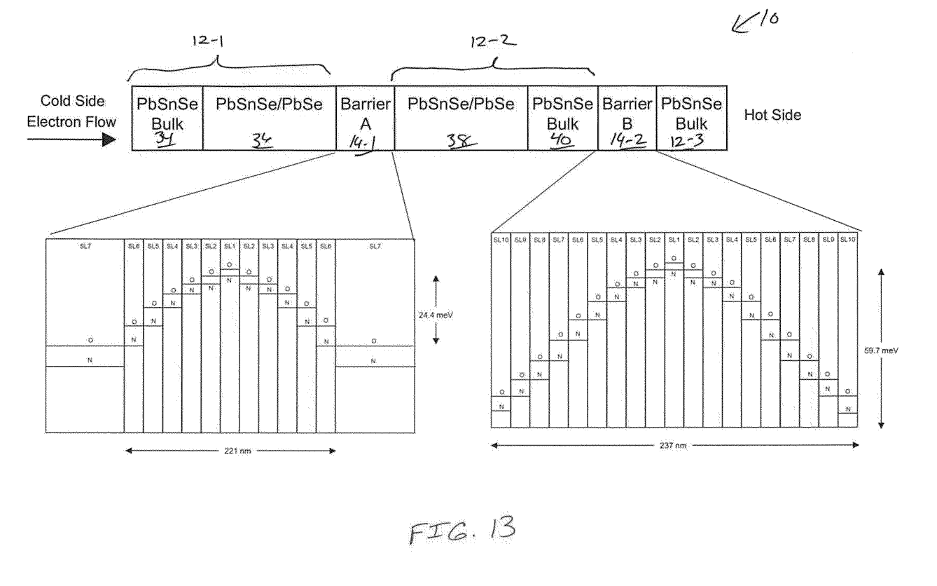

FIG. 13 illustrates one embodiment of the thermoelectric material 10 of FIG. 1 in which the barrier material layer 14-1 is the barrier material layer 14 of FIG. 11 and the barrier material layer 14-2 is the barrier material layer 14 of FIG. 12. In this particular embodiment, the barrier material layer 14-1 is near a cold side of the thermoelectric material 10 during operation whereas the barrier material layer 14-2 is near a hot side of the thermoelectric material 10 during operation. In this embodiment, the matrix material layer 12-1 includes a PbSnSe bulk layer 34 and a PbSnSe/PbSe superlattice layer 36 having a quantum well width (and thus sub-band energy levels) that is equal to that of the adjacent superlattice layer 16-1 in the barrier material layer 14-1. The superlattice layer 36 effectively lowers a barrier height of the barrier material layer 14-1, which is preferable near the cold side of the thermoelectric material 10. The matrix material layer 12-2 includes a PbSnSe/PbSe superlattice layer 38 having a quantum well width (and thus sub-band energy levels) that is equal to that of the adjacent superlattice layer 16-13 in the barrier material layer 14-1 and a PbSnSe bulk layer 40. The low band-gap of the PbSnSe bulk layer 40 increases a barrier height of the barrier material layer 14-2, which is preferable near the hot side of the thermoelectric material 10. In this example, the barrier height of the barrier material layer 14-1 is 24.4 meV, and the barrier height of the barrier material layer 14-2 is 59.7 meV.

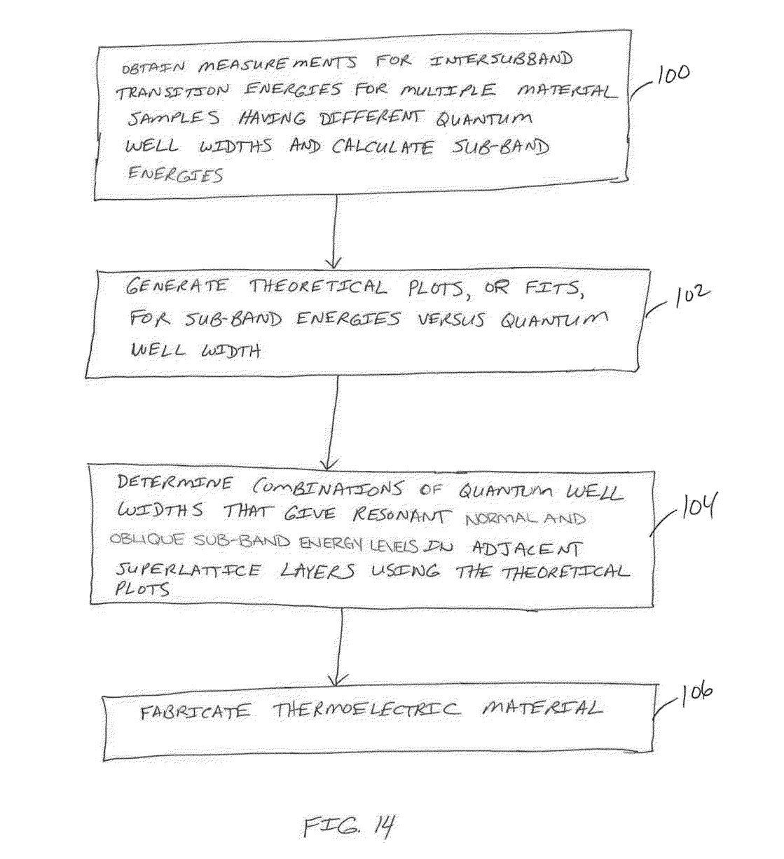

FIG. 14 is a flow chart that illustrates a method of designing and fabricating the thermoelectric material 10 of FIG. 1 for Group IV-VI materials according to one embodiment of the present disclosure. Note that the same or a similar process may be used to design and fabricate the thermoelectric material 10 in other material systems. First, measurements for intersubband transition energies for multiple quantum well material samples having different quantum well widths are obtained and normal and oblique valley sub-band energy levels are calculated (step 100). The sub-band energy levels are calculated in the conduction and valence bands assuming equal band edge discontinuities between the well and barrier materials. Next, using Schrödinger's equation, theoretical fits, or theoretical plots, of the energy levels for the normal and oblique valley sub-bands versus quantum well width are generated (step 102). More specifically, the effective masses for electrons and holes in the normal and oblique valley sub-bands are adjusted to determine theoretical plots that best fit the measurements obtained in step 100. Next, the theoretical curves for sub-band energy versus quantum well width are used to determine combinations of quantum well widths that give resonant, or equal, normal and oblique valley sub-band energy levels in adjacent superlattice layers 16 in the short period superlattice structure of the barrier material layer 14 (step 104). Lastly, the combinations of the quantum well widths determined in step 104 are used to fabricate the thermoelectric material 10 (step 106).

Those skilled in the art will recognize improvements and modifications to the preferred embodiments of the present disclosure. All such improvements and modifications are considered within the scope of the concepts disclosed herein and the claims that follow.

What is claimed is:

1. A thermoelectric material comprising:
a first matrix material layer;
a barrier layer on the first matrix material layer, the barrier layer having a short-period superlattice structure comprising a plurality of superlattice layers wherein each superlattice layer of the plurality of superlattice layers has at least one characteristic selected from a group consisting of: a high energy sub-band that is resonant with a low energy sub-band of an adjacent superlattice layer in the plurality of superlattice layers and a low energy sub-band that is resonant with a high energy sub-band of an adjacent superlattice layer in the plurality of superlattice layers; and
a second matrix material layer on the barrier layer.

2. The thermoelectric material of claim 1 wherein the plurality of superlattice layers comprise:
a superlattice layer having a maximum bandgap for the barrier layer;
a first set of successive superlattice layers immediately preceding the superlattice layer having the maximum bandgap for the barrier layer, wherein, for each superlattice layer in the first set of successive superlattice layers, the high energy sub-band for the superlattice layer is resonant with a low energy sub-band for an immediately succeeding superlattice layer; and
a second set of successive superlattice layers immediately succeeding the superlattice layer having the maximum bandgap of the barrier layer, wherein, for each superlattice layer in the second set of successive superlattice layers, the high energy sub-band for the superlattice layer is resonant with a low energy sub-band for an immediately preceding superlattice layer.

3. The thermoelectric material of claim 1 wherein the thermoelectric material is formed in a Group IV-VI materials system.

4. The thermoelectric material of claim 3 wherein the high energy sub-bands of the plurality of superlattice layers are oblique valley sub-bands, and the low energy sub-bands of the plurality of superlattice layers are normal valley sub-bands.

5. The thermoelectric material of claim 4 wherein each superlattice layer of the plurality of superlattice layers is a periodic structure formed of alternating layers of Lead Selenide and Lead Strontium Selenide.

6. The thermoelectric material of claim 4 wherein each superlattice layer of the plurality of superlattice layers is a periodic structure formed of alternating layers of Lead Selenide and Lead Tin Selenide.

7. The thermoelectric material of claim 1 further comprising:
a second barrier layer on the second matrix material layer, the second barrier layer having a short-period superlattice structure comprising a second plurality of superlattice layers wherein each superlattice layer of the second plurality of superlattice layers has at least one characteristic selected from a group consisting of: a high energy sub-band that is resonant with a low energy sub-band of an adjacent superlattice layer in the second plurality of superlattice layers and a low energy sub-band that is resonant with a high energy sub-band of an adjacent superlattice layer in the second plurality of superlattice layers; and
a third matrix material on the second barrier layer.

8. The thermoelectric material of claim 7 wherein a barrier height of the second barrier layer is different than a barrier height of the barrier layer.

9. The thermoelectric material of claim 1 wherein each superlattice layer of the plurality of superlattice layers has a thickness that is approximately equal to a mean free path distance of charge carriers between scattering events for a corresponding temperature in a temperature gradient for which the thermoelectric material is designed.

10. The thermoelectric material of claim 1 wherein the plurality of superlattice layers are further configured to reflect a plurality of phonon wavelengths, the plurality of superlattice layers comprising, for each phonon wavelength of the plurality of phonon wavelengths, a plurality of layers of one material composition each having a thickness approximately equal to a quarter of the phonon wavelength and a plurality of layers of another material composition each having a thickness approximately equal to a quarter of the phonon wavelength.

11. A method of fabricating a thermoelectric material, comprising:
providing a first matrix material layer;
providing a barrier layer on the first matrix material layer, the barrier layer having a short-period superlattice structure comprising a plurality of superlattice layers wherein each superlattice layer of the plurality of superlattice layers has at least one characteristic selected from a group consisting of: a high energy sub-band that is resonant with a low energy sub-band of an adjacent superlattice layer in the plurality of superlattice layers and a low energy sub-band that is resonant with a high energy sub-band of an adjacent superlattice layer in the plurality of superlattice layers; and
providing a second matrix material layer on the barrier layer.

12. The method of claim 11 wherein the plurality of superlattice layers comprise a superlattice layer having a maximum bandgap for the barrier layer, and providing the plurality of superlattice layers comprise:
providing a first set of successive superlattice layers immediately preceding the superlattice layer having the maximum bandgap for the barrier layer, wherein, for each superlattice layer in the first set of successive superlattice layers, the high energy sub-band for the superlattice layer is resonant with a low energy sub-band for an immediately succeeding superlattice layer;
providing the superlattice layer having the maximum bandgap for the barrier layer on the first set of successive superlattice layers; and
providing a second set of successive superlattice layers immediately succeeding the superlattice layer having the maximum bandgap for the barrier layer, wherein, for each superlattice layer in the second set of successive superlattice layers, the high energy sub-band for the superlattice layer is resonant with a low energy sub-band for an immediately preceding superlattice layer.

13. The method of claim 11 wherein the thermoelectric material is formed in a Group IV-VI materials system.

14. The method of claim 13 wherein the high energy sub-bands of the plurality of superlattice layers are oblique valley sub-bands, and the low energy sub-bands of the plurality of superlattice layers are normal valley sub-bands.

15. The method of claim 14 wherein providing the barrier layer comprises, for each superlattice layer of the plurality of superlattice layers, providing the superlattice layer as a periodic structure formed of alternating layers of Lead Selenide and Lead Strontium Selenide.

16. The method of claim 14 wherein providing the barrier layer comprises, for each superlattice layer of the plurality of superlattice layers, providing the superlattice layer as a periodic structure formed of alternating layers of Lead Selenide and Lead Tin Selenide.

17. The method of claim 11 further comprising:
providing a second barrier layer on the second matrix material layer, the second barrier layer having a short-period superlattice structure comprising a second plurality of superlattice layers wherein each superlattice layer of the second plurality of superlattice layers has at least one characteristic selected from a group consisting of: a high energy sub-band that is resonant with a low energy sub-band of an adjacent superlattice layer in the second plurality of superlattice layers and a low energy sub-band that is resonant with a high energy sub-band of an adjacent superlattice layer in the second plurality of superlattice layers; and
providing a third matrix material on the second barrier layer.

18. The method of claim 17 wherein a barrier height of the second barrier layer is different than a barrier height of the barrier layer.

19. The method of claim 11 wherein providing the barrier layer comprises providing each superlattice layer of the plurality of superlattice layers such that the superlattice layer has a thickness that is approximately equal to a mean free path distance of charge carriers between scattering events for a corresponding temperature in a temperature gradient for which the thermoelectric material is designed.

20. The method of claim 11 wherein providing the barrier layer comprises providing the plurality of superlattice layers such that the plurality of superlattice layers comprise, for each phonon wavelength of a plurality of phonon wavelengths desired to be blocked, a plurality of layers of one material composition each having a thickness approximately equal to a quarter of the phonon wavelength and a plurality of layers of another material composition each having a thickness approximately equal to a quarter of the phonon wavelength.

21. A method comprising:
obtaining measurements for intersubband transition energies for a plurality of samples of a desired material having different quantum well widths;
calculating sub-band energies for the plurality of samples of the desired material;
generating a representation of theoretical values for sub-band energies for the desired material versus quantum well width based on the sub-band energies calculated for the plurality of samples of the desired material;
determining combinations of quantum well widths that provide resonant high energy and low energy sub-bands for adjacent superlattice layers in a barrier layer of a thermoelectric material; and
fabricating the thermoelectric material such that the thermoelectric material comprises the barrier layer having the combinations of quantum well widths that provide the resonant high energy and low energy sub-bands.
